(19) United States
(12) Patent Application Publication
(10) Pub. No.: US 2026/0334224 A1
(43) Pub. Date: Oct. 22, 2026

(54) Semiconductor Device Package with Heat Spreader

(71) Applicant: Sandisk Technologies, Inc., Milpitas, CA (US)

(72) Inventors: Raghavan Nagarajan, Karnataka (IN); Hariharapandian S, Karnataka (IN); Apratim Sanyal, Karnataka (IN); Chaolun Zheng, Milpitas, CA (US)

(73) Assignee: Sandisk Technologies, Inc., Milpitas, CA (US)

(21) Appl. No.: 19/185,770

(22) Filed: Apr. 22, 2025

(51) Int. Cl. H01L 23/373; H01L 23/04; H01L 23/538; H01L 25/00; H01L 25/16; H10B 80/00

(52) U.S. Cl. CPC H10W 40/255; H10W 70/611; H10W 70/688; H10W 70/699; H10W 76/12; H10W 90/00; H10W 90/401; H10B 80/00

(57) ABSTRACT

A semiconductor device package includes a rigid substrate having an interconnect layer. A semiconductor die is electrically connected to and mounted directly on the rigid substrate. A flexible substrate electrically connects to and extends outwardly from the rigid substrate. The flexible substrate includes a thermally conductive layer that is electrically connected to the interconnect layer of the rigid substrate. A heat spreader is physically connected to the flexible substrate opposite the rigid substrate and is electrically connected to the thermally conductive layer of the flexible substrate. Providing a heat spreader connected to the rigid substrate via the flexible substrate may increase thermal performance of the semiconductor device package while maintaining space efficiency within a host system.

### BACKGROUND

The present invention generally relates to semiconductor devices and more particularly to semiconductor device packages having an integrated heat spreader for dissipating heat generated by the semiconductor device package.

Thermal dissipation in electronic devices and systems is typically achieved through mechanisms that transfer heat away from the components which generate it. However, for relatively small electronic device packages such as removable memory cards (e.g., secure digital (SD) cards), achieving efficient heat dissipation is difficult due to the limited form factor of the memory card itself and/or the card socket for which it is to be connected. Conventional dissipation mechanisms for small form factor devices and related systems often require increasing the overall size of those systems and/or modifying main circuit boards to which they are connected. However, such modifications and increases in size are generally undesirable and often increase cost and complexity of design. Additionally, poor thermal dissipation may lead to performance throttling of memory cards and the like in order to meet thermal requirements of the dies (e.g., NAND dies) and circuitry (e.g., ASICs) of the memory cards. Accordingly, there is a need to provide a semiconductor device package with improved integrated thermal dissipation capabilities that require little to no modification of the sockets and/or main circuit boards for which the semiconductor device package is connected to.

### SUMMARY

In one embodiment there is a semiconductor device package including a first rigid substrate including an interconnect layer, a semiconductor die electrically connected to and mounted directly on the first rigid substrate, a flexible substrate electrically connected to and extending outwardly from the first rigid substrate, the flexible substrate including a thermally conductive layer that is electrically connected to the interconnect layer of the first rigid substrate, and a heat spreader physically connected to the flexible substrate opposite the first rigid substrate, the heat spreader being electrically connected to the thermally conductive layer of the flexible substrate.

In some embodiments, the interconnect layer and thermally conductive layer form a continuous electrically conductive layer. In some embodiments, the interconnect layer is an electrical ground plane of the first rigid substrate. In some embodiments, the first rigid substrate is configured to be positioned within and electrically connected to a memory card socket and the heat spreader is configured to be mounted to an exterior surface of the memory card socket via a thermal interface material. In some embodiments, the semiconductor die is mounted to a top surface of the first rigid substrate and the flexible substrate is physically connected to the first rigid substrate at a side surface thereof that extends between the top surface and an opposed bottom surface.

In some embodiments, the heat spreader includes a second rigid substrate that is physically connected to the flexible substrate and electrically connects the thermally conductive layer of the flexible substrate to a thermal conduction plate that is exposed at a bottom surface of the second rigid substrate. In some embodiments, the thermal conduction plate is a layer of copper or a copper alloy that is electrically connected to the second rigid substrate and directly mounted to the bottom surface thereof. In some embodiments, the thermally conductive layer is continuous and comprises a layer of copper or a copper alloy that extends through the first rigid substrate, the flexible substrate, and the second rigid substrate.

In another embodiment, there is a semiconductor device system including a semiconductor device package including, a first rigid substrate including an interconnect layer, a semiconductor die electrically connected to and mounted directly on the first rigid substrate, a flexible substrate electrically connected to and extending outwardly from the first rigid substrate, the flexible substrate including a thermally conductive layer that is electrically connected to the interconnect layer of the first rigid substrate, and a heat spreader physically connected to the flexible substrate opposite the first rigid substrate, the heat spreader being electrically connected to the thermally conductive layer of the flexible substrate. The semiconductor device package further including a card socket including a slot interface within which the first rigid substrate is positioned, the slot interface including an electrical contact that is electrically connected to a contact pad of the first rigid substrate, and a housing surrounding the slot interface, the housing including an exterior surface upon which the heat spreader is mounted.

In some embodiments, the flexible substrate extends outside of the slot interface from the first rigid substrate to the heat spreader. In some embodiments, the semiconductor device system further includes a thermal interface material adhering the heat spreader to the exterior surface of the housing. In some embodiments, the semiconductor device system further includes a main circuit board including an electrical ground plane, the card socket is mounted to the main circuit board and the housing thereof is electrically connected to the electrical ground plane and the interconnect layer is an electrical ground plane of the first rigid substrate.

In some embodiments, the heat spreader includes a second rigid substrate that is physically connected to the flexible substrate and electrically connects the thermally conductive layer of the flexible substrate to a thermal conduction plate that is exposed at a bottom surface of the second rigid substrate. In some embodiments, the thermal conduction plate is adhered to the exterior surface of the housing via a thermal interface material. In some embodiments, the thermally conductive layer is continuous and comprises a layer of copper or a copper alloy that extends through the first rigid substrate, the flexible substrate, and the second rigid substrate.

In another embodiment there is a method of connecting a semiconductor device package to a corresponding card socket, the method including positioning a first rigid substrate of the semiconductor device package within a slot interface of the card socket such that a semiconductor die mounted to the first rigid substrate is electrically connected to the slot interface, and mounting a heat spreader to an exterior surface of the card socket, the heat spreader being electrically connected to an interconnect layer of the first rigid substrate via a flexible substrate that electrically connect to and extends outwardly from the first rigid substrate, the flexible substrate including a thermally conductive layer that is electrically connected to the interconnect layer of the first rigid substrate and to the heat spreader.

In some embodiments, mounting the heat spreader to the exterior surface of the card socket includes adhering an exposed thermally conductive plate of the heat spreader to the exterior surface via a thermal interface material. In some embodiments, mounting the heat spreader to the exterior surface of the card socket causes the interconnect layer of the first rigid substrate to be electrically connected to an electrical ground plane of a main circuit board upon which the card socket is mounted. In some embodiments, the thermally conductive layer is continuous and comprises a layer of copper or a copper alloy that extends through the first rigid substrate, the flexible substrate, and the heat spreader.

### BRIEF DESCRIPTION OF THE DRAWINGS

The foregoing summary, as well as the following detailed description, will be better understood when read in conjunction with the appended drawings. For the purpose of illustrating the present disclosure, there are shown in the drawings embodiments, which are presently preferred, wherein like reference numerals indicate like elements throughout. It should be noted, however, that aspects of the present disclosure can be embodied in different forms and thus should not be construed as being limited to the illustrated embodiments set forth herein. The elements illustrated in the accompanying drawings are not necessarily drawn to scale, but rather, may have been exaggerated to highlight the important features of the subject matter therein. Furthermore, the drawings may have been simplified by omitting elements that are not necessarily needed for the understanding of the disclosed embodiments.

In the drawings:

FIG. 1 is a cross-sectional view of a semiconductor device system in accordance with an exemplary embodiment of the present disclosure;

FIG. 2 is a diagram illustrating layers of a semiconductor device package included in the system of FIG. 1;

FIGS. 3-5 illustrate a method of connecting a semiconductor device package to a corresponding card socket in accordance with an exemplary embodiment of the present disclosure.

### DETAILED DESCRIPTION

The present subject matter will now be described more fully hereinafter with reference to the accompanying Figures, in which representative embodiments are shown. The present subject matter can, however, be embodied in different forms and should not be construed as limited to the embodiments set forth herein. Rather, these embodiments are provided to describe and enable one of skill in the art.

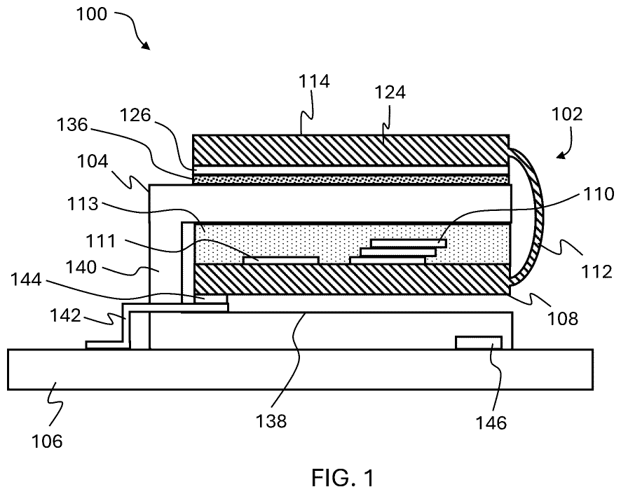

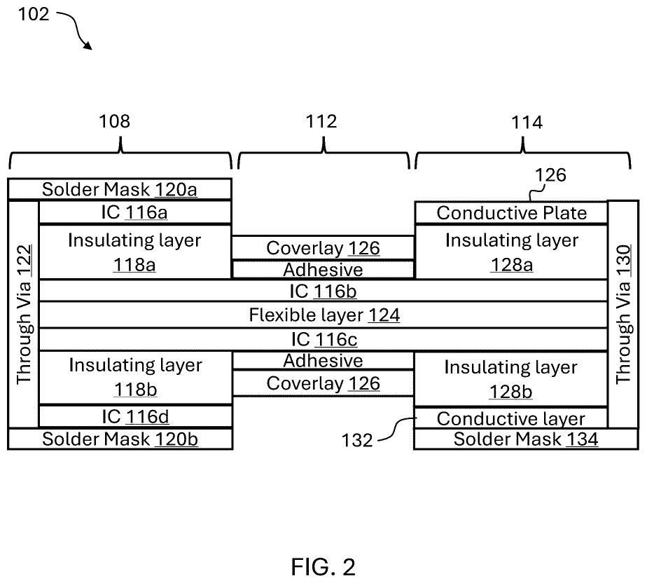

Referring to FIGS. 1-2, there is shown a semiconductor device system, generally designated 100, in accordance with an exemplary embodiment of the present disclosure. The semiconductor device system 100, or system 100 for short, may include a semiconductor device package 102 and a card socket 104 configured to receive the semiconductor device package 102. The card socket 104 may generally be a connection means for electrically and/or mechanically coupling the semiconductor device package 102 to a main circuit board 106. The card socket 104 may be a port sized to receive the semiconductor device package 102. For example, in some embodiments, the semiconductor device package 102 is an SD card dimensioned according to industry standards and the card socket 104 is sized to receive the SD card.

The main circuit board 106 may be a substrate configured to act as a mechanical base support for the electrical components connected thereto and/or an electrical interface (or electrical circuit) that provides access to said electrical components. For example, the main circuit board 106 is a printed circuit board (PCB) including a plurality of layers for providing mechanical support and/or electrical pathways. The main circuit board 106 illustrated in the Figures may only represent a portion of the main circuit board 106 and it should be understood that components other than the ones discussed herein may be attached to the main circuit board 106. In some embodiments, the main circuit board 106 includes an electrical circuit (not shown) having a plurality of metal layers and/or traces disposed therein, including one or more layers for routing signals such as, but not limited to, input/output signals, power signals, and ground signals using conductive (e.g., copper) traces. In some embodiments, the main circuit board 106 includes an electrical ground plane for electrically grounding one or more components electrically connected thereto.

The semiconductor device package 102 may include a first rigid substrate 108, a semiconductor die 110, a flexible substrate 112, and a heat spreader 114. The first rigid substrate 108 may be a mechanical base support for the electrical components connected thereto and an electrical interface (or electrical circuit) that provides access to said electrical components. In some embodiments, the first rigid substrate 108 includes an electrical circuit having a plurality of metal layers and/or traces disposed within the first substrate 102, including one or more layers for routing signals such as, but not limited to, input/output signals, power signals, and ground signals using conductive (e.g., copper) traces. For example, and as illustrated in FIG. 2, the first rigid substrate 108 includes a plurality of interconnect (IC) layers 116a-116d comprised of a conductive material (e.g., copper, copper alloy). In some embodiments, the first rigid substrate 108 includes one or more electrically insulating layers 118a-118b. In some embodiments, the insulating layers 118a-118b are comprised of an electrically insulating material (e.g., fiberglass epoxy (FR4), bismaleimide triazine (BT) resin). The insulating layers 118a-118b, in some embodiments, provide mechanical strength and rigidity to the first rigid substrate 108 and may be thicker than the respective interconnect layers. It should be understood that the first rigid substrate 108 is not limited to the number of electrically conductive layers and the number of electrically insulating layers illustrated in FIG. 2.

The first rigid substrate 108 may include solder mask layers 120a, 120b at the top and bottom surfaces thereof for protecting the conductive layers from oxidation and corrosion. The solder mask layers 120a, 120b may be generally be a protective coating and may be comprised of an epoxy or similar material. In some embodiments, the first rigid substrate 108 includes one or more through vias 122 for providing electrical pathways between the different IC layers 116a-116d. Although a single via 122 is illustrated in FIG. 2 it should be understood that the first rigid substrate 108 may include any number of vias 122 extending between one or more of the IC layers 116a-116d as desired. The IC layers 116a-116d and/or via 122 may enable electrical communications to be transmitted to and from one or more electrical components coupled to the first rigid substrate 108. For example, the semiconductor die 110 may be electrically connected to one or more of the IC layers 116a-116d and/or via 122.

The semiconductor die 110 may be electrically connected to and mounted directly on the first rigid substrate 108. The semiconductor die 110 may generally be a storage means for providing an amount of data storage to the semiconductor device package 102. In some embodiments, the semiconductor die 110 may be a stack of semiconductor dies. The semiconductor die 110 may be a memory die (e.g., a NAND die), an application specific integrated circuit (ASIC), a controller die, or any other integrated circuit (IC) die. In some embodiments, there is a memory controller 111 electrically connected to and mounted directly on the first rigid substrate 108. The memory controller 111 may generally be a controlling means for controlling communication to the semiconductor die 110. In some embodiments, the memory controller 111 is an ASIC, an IC die or any other suitable control die for controlling operation of the semiconductor dies 110. The semiconductor die(s) 110 and/or memory controller 111 may be encapsulated within a molding compound 113 (e.g., an epoxy molding compound (EMC)).

During use the semiconductor die 110 and/or memory controller 111 may generate heat which may be dissipated away from the semiconductor device package 102 via the flexible substrate 112 and/or heat spreader 114. The flexible substrate 112 may be configured to provide a thermal pathway from the first rigid substrate 108 to the heat spreader 114. For example, heat generated by the semiconductor die 110 and/or memory controller 111 moves from the first rigid substrate 108 through the flexible substrate 112 and to the heat spreader 114 via thermal conduction.

The flexible substrate 112 may be electrically connected to and extend outwardly from the first rigid substrate 108. The flexible substrate 112 may extend outwardly from a side surface of the first rigid substrate 108. The flexible substrate 112 may connect to the first rigid substrate 108 at one end and to the heat spreader 114 at an opposite end thereof. In some embodiments, the flexible substrate includes a thermally conductive layer that is electrically connected to an IC layer 116a-116d of the first rigid substrate 108 for conducting heat away from the first rigid substrate 108. A thermally conductive layer and/or component of the semiconductor device system 100 as discussed herein may generally refer to a layer and/or component configured to effectively conduct heat. For example, a thermally conductive layer and/or component as discussed herein may be comprised of a thermally conductive material (e.g., a metal) such as, but not limited to, copper, aluminum, and silver. In some embodiments, a thermally conductive material may be a material having a thermal conductivity of at least 100 W/m*K.

In some embodiments, the thermally conductive layer of the flexible substrate 112 forms a continuous electrically conductive layer with one or more of IC layers 116a-116d of the first rigid substrate 108. For example, and as illustrated in FIG. 2, the interconnect layers 116b-116c are continuous and extend from the first rigid substrate 108, through the flexible substrate 112 and to the heat spreader 114. Accordingly, in the example illustrated in FIG. 2, the interconnect layers 116b-116c form the thermally conductive layer(s) of the flexible substrate 112. In some embodiments, the thermally conductive layer of the flexible substrate 112 is formed from a single continuous IC layer 116a-116d of the first rigid substrate 108. In some embodiments, the thermally conductive layer(s) of the flexible substrate 112 is electrically connected to an electrical ground plane of the first rigid substrate 108. For example, the IC layers 116b-116c may be electrical ground planes of the first rigid substrate 108. Accordingly, heat may be conducted from the semiconductor die(s) 110, and/or memory controller 111 to the heat spreader 114 through an electrical ground plane of the semiconductor device package 102. In some embodiments, the semiconductor device package 102 is configured to dissipate heat generated therefrom to an electrical ground plane of the main circuit board 106 as discussed in more detail below. In some embodiments, dissipating heat from the semiconductor device package 102 via ground plane(s) of the main circuit board 106 and/or substrate 108 may allow for effective heat dissipation through existing electrical pathways thereof. The ground plane(s) of the main circuit board 106 and substrate 108 may be larger in area than other electrical layers for routing input/output signals and/or power signals. Accordingly, the ground plane(s) may have a higher thermal conductivity than the other electrical layers.

In some embodiments, the flexible substrate 112 and first rigid substrate 108 are integrally formed. For example, and as illustrated in FIG. 2, the flexible substrate 112 and first rigid substrate 108 share continuous layers with one another. In some embodiments, the flexible substrate 112 is configured to be generally flexible as compared to the first rigid substrate 108. The flexible substrate 112 may include a flexible layer 124 that allows the flexible substrate 112 to be bent, flexed or otherwise provide pliability to the flexible substrate 112. In some embodiments, the flexible layer 124 is comprised of a generally flexible and electrically insulating material (e.g., polymide). In some embodiments, the flexible layer 124 extends continuously through the flexible substrate 112 and at least partially through the first rigid substrate 108 and/or heat spreader 114. In such embodiments, the first rigid substrate 108 may remain generally rigid throughout due to the rigidity of the insulating layers 118a, 118b. For example, although the flexible layer 124 extends at least partially through the first rigid substrate 108, the insulating layers 118a, 118b are comprised of a rigid and electrically insulating material (e.g., FR4) thereby causing the first rigid substrate 108 to be generally rigid.

The flexible substrate 112 may be devoid of insulating layers 118a, 118b and generally rigid materials such that it is generally flexible and/or pliable. In some embodiments, the flexible substrate 112 includes coverlays 126 that cover to the portions of IC layers 116b, 116c that protrude from the first rigid substrate 108 such that they are not exposed. In some embodiments, the coverlays 126 are adhered to the IC layers 116b-116c via adhesive layers.

The heat spreader 114 may be electrically connected to the flexible substrate 112 and configured to dissipate heat generated by the semiconductor device package 100. The heat spreader 114 may be physically connected to the flexible substrate 112 opposite the first rigid substrate 108. For example, the heat spreader 114 is connected to the flexible substrate 112 at an end opposite the first rigid substrate 108. In some embodiments, the heat spreader 114 is electrically connected to the thermally conductive layer of the flexible substrate 112. For example, and as illustrated in FIG. 2, the IC layers 116b-116c that form the thermally conductive layer of the flexible substrate 112 are generally continuous and extend from the first rigid substrate 108 through the flexible substrate 112 and to the heat spreader 114. Accordingly, the IC layers 116b-116c may be a continuous electrically and thermally conductive layer that extends through the first rigid substrate 108, flexible layer 112 and heat spreader 114.

In some embodiments, the heat spreader 114 includes a second rigid substrate 124 that is physically connected to the flexible substrate 112. The second rigid substrate 124 may may include one or more exposed conductive layers for conducting heat away from the semiconductor device package 102. The heat spreader 114 may include a thermal conduction plate 126 that is exposed at a bottom surface of the second rigid substrate 124. The second rigid substrate 124 may be generally similar to the first rigid substrate 108 except that it may include the exposed conductive layer (e.g., the conduction plate 126). The second rigid substrate 124 may include insulating layers 128a-128b that are generally the same as insulating layers 118a-118b. In some embodiments, the insulating layers 128a-128b are comprised of a generally rigid and electrically insulating material (e.g., FR4). The second rigid substrate 124 may include a through via 130 generally the same as through via 122 discussed above. The second rigid substrate 124 may include a conductive layer 132 and solder mask 134 at the bottom surface thereof.

The second rigid substrate 124 may generally be configured to conduct heat to the exposed conductive plate 126 such that the heat may be dissipated from the semiconductor device package 102. In some embodiments, the second rigid substrate 124 includes fewer conductive and insulating layers than the first rigid substrate 108. For example, although FIG. 2 illustrates a generally mirrored layered configuration, the first rigid substrate 108 may include more interconnect layers and/or electrically insulating layers as desired to route electrical signals to and from the semiconductor dies 110 mounted thereto. There may be no semiconductor dies (e.g., memory dies, controller dies) mounted directly to second rigid substrate 124. The second rigid substrate 124 may include fewer electrical pathways than the first rigid substrate 108 and/or may have a thickness that is less than a thickness of the first rigid substrate 108.

In some embodiments, the exposed conductive plate 126 defines substantially all of the bottom surface of heat spreader 114. For example, the exposed conductive plate 126 may be a generally continuous copper layer that covers entirely the bottom surface of the second rigid substrate 124. The conductive plate 126 may generally be a thermal interface means or thermal interface surface 126 through which heat is to be conducted to a connected surface. Accordingly, as the cross-sectional area of the conductive plate 126 is increased the heat dissipation capabilities thereof also increase. Accordingly, the conductive plate 126 may be sized as desired to achieve a desired heat transfer rate.

In some embodiments, one or more holes may be formed in the conductive plate 126 through which via 130 may extend and electrically connect to the conductive plate 126. In other embodiments, the conductive plate 126 is substantially devoid of holes or openings and the via 130 directly contacts the conductive plate 126. Although a single via 130 is shown in FIG. 2, it should be understood that the heat spreader 114 may include a plurality of vias 130 electrically connecting one or more of the electrically conductive layers thereof. The vias 130 may be comprised of a thermally conductive material such that heat may be effectively transferred to the conductive plate 126. The via 130 may electrically and/or thermally connect the conductive plate 126 to the thermally conductive layer of the flexible substrate 112. Accordingly, the thermally conductive layer of the flexible substrate 112 and via(s) 130 may define a thermally conductive pathway for heat to be transferred from the first rigid substrate 108 to the conductive plate 126. The thermal conduction plate 126 may be a layer of copper or a copper alloy that is electrically connected to the second rigid substrate 124 (e.g., by via 130) and directly mounted to the bottom surface thereof.

In some embodiments, the first rigid substrate 108 is configured to be positioned within and electrically connected to the card socket 104 and the heat spreader 114 is configured to be mounted to an external surface of the card socket 104 via a thermal interface material (TIM) 136. The heat spreader 114 may be configured to dissipate heat generated from the semiconductor device package 102 to the card socket 104. The TIM 136 may be a material for improving heat transfer efficiency between the heat spreader 114 and card socket 104. For example, TIM 136 is a thermal paste, thermal tape, or the like that is comprised of a thermally and/or electrically conductive material. In some embodiments, the heat spreader 114 is adhered to the card socket 104 via TIM 136.

The card socket 104 may include a slot interface 138 within which the first rigid substrate 108 may be positioned and a housing 140 surrounding the slot interface 138. The slot interface 138 may be a receptacle formed in the housing 140 and configured to electrically connect the first rigid substrate 108 to the main circuit board 106. The slot interface 138 may include one or more electrical contacts 142 that may electrically and/or physically connect to a contact pad 144 of the first rigid substrate 108. In some embodiments, the electrical contact 142 includes an electrical pathway (e.g., a trace) extending to the main circuit board 106 such that the electrical contact 142 and main circuit board 106 are electrically connected to one another. The contact pad 144 of the first rigid substrate 108 may be electrically connected to the substrate 108 and to the die(s) 110 and/or memory controller 111 such that electrical signals may be transmitted between the main circuit board 106 and die(s) 110 and/or memory controller 111. Although not shown it should be understood that there may be a plurality of electrical contacts 142 and contact pads 144 physically and electrically connected to one another when the substrate 108 is connected to the slot interface 138 of the card socket 104. In some embodiments, the contact pad(s) 144 are positioned along the substrate 108 at an end opposite the flexible substrate 112.

In some embodiments, the card socket 104 is designed according to industry standards for a corresponding semiconductor memory card. For example, and as discussed above, the semiconductor memory device 102 may include a memory card sized according to one or more industry standards, such as, but not limited to an SD card. The first rigid substrate 108, semiconductor die(s) 110, memory controller 111, molding compound 113 and contact pad(s) 144 may form a memory device (e.g., a memory card, an SD card) that is generally sized according to one or more corresponding industry standards. For example, the number of contact pads 144 and the dimensions of the combined substrate 108 and molding compound 113 may correspond to those of an SD memory card. Accordingly, the slot interface 138 of the card socket 104 may be sized to receive the first rigid substrate 108 and the components directly connected thereto while the flexible substrate 112 extends out of the slot interface 138.

The housing 140 may be a protective outer shell or structure that defines the slot interface 138 and the overall footprint of the card socket 104 on the main circuit board 106. The housing 140 may be comprised of an electrically and/or thermally conductive material. For example, the housing 140 is comprised of a metal or metal alloy that is electrically and thermally conductive. In some embodiments, the housing 140 is electrically connected to an electrical ground plane of the main circuit board 106. The card socket 104 may include one or more electrical ground pins 146 that electrically connect the card socket 104 to a ground plane of the main circuit board 106.

The housing 140 may define one or more exterior surfaces of the card socket upon which the heat spreader 114 may be mounted. For example, and as illustrated in FIG. 1, the heat spreader 114 is mounted directly to the top exterior surface of the housing 140 via the TIM 136. In some embodiments, mounting the heat spreader 114 to an external surface of the housing 140 allows for heat to be dissipated from the heat spreader 114 to the housing 140 thereby improving thermal performance of the memory die(s) 110 and/or memory controller 111. In some embodiments, mounting the heat spreader 114 to the top external surface of the housing 140 allows for heat to be dissipated from the semiconductor device package 102 while minimizing footprint of the semiconductor device system 100 (e.g., improving thermal performance and spatial efficiency). In some embodiments, dissipating heat from the semiconductor device package 102 via the heat spreader 114 of the present disclosure minimizes the risk of thermal throttling and allows the semiconductor device package 102 to operate in a high-performance manner.

When mounted to the housing 104, an electrical ground plane of the first rigid substrate 108 may be electrically connected to the electrical ground plane of the main circuit board 106. The heat spreader 114 may be electrically connected to the ground plane of the main circuit board 106 via the electrical pathway from the electrically conductive housing 140 to the ground pin(s) 146. Accordingly, an electrical ground pathway from the first rigid substrate 108 to the main circuit board 106, may be defined by the flexible substrate 112, heat spreader 114, and housing 140. In some embodiments, the flexible substrate 112 extends outside of the slot interface 138 from the first rigid substrate 108 to the heat spreader 114 when the semiconductor device package 100 is connected to the card socket 104.

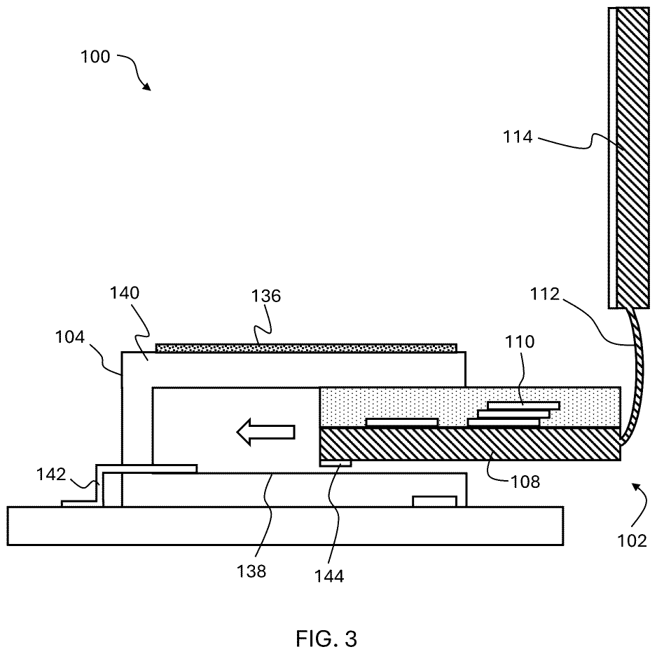

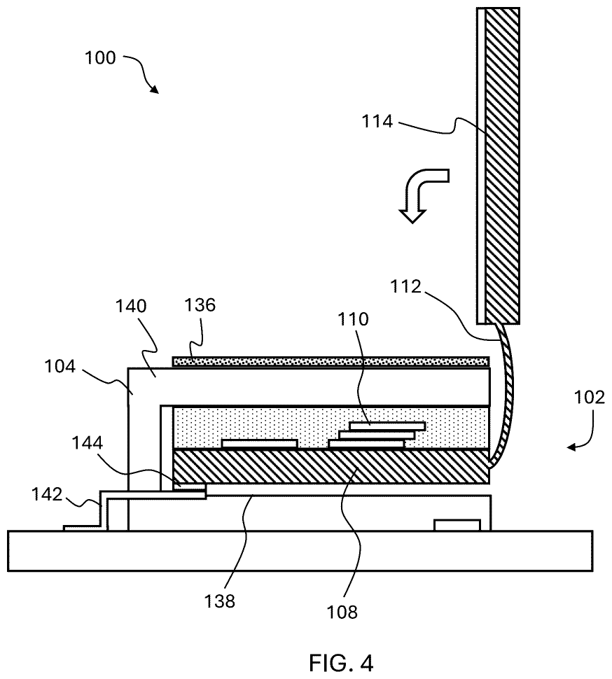

Referring to FIGS. 3-5 there is illustrated a method of connecting a semiconductor device package (e.g., semiconductor device package 102) to a corresponding card socket (e.g., card socket 104) in accordance with an exemplary embodiment of the present disclosure. As shown in FIGS. 3-4, the method may include positioning a first rigid substrate 108 of the semiconductor device package 102 within a slot interface 138 of the card socket 104 such that a semiconductor die 110 mounted to the first rigid substrate 108 is electrically connected to the slot interface 138. For example, and as illustrated by the arrow in FIG. 3, the first rigid substrate 108 is moved into the position shown in FIG. 4 such that the contact pad 144 is physically and electrically connected to electrical contact 142 as discussed above.

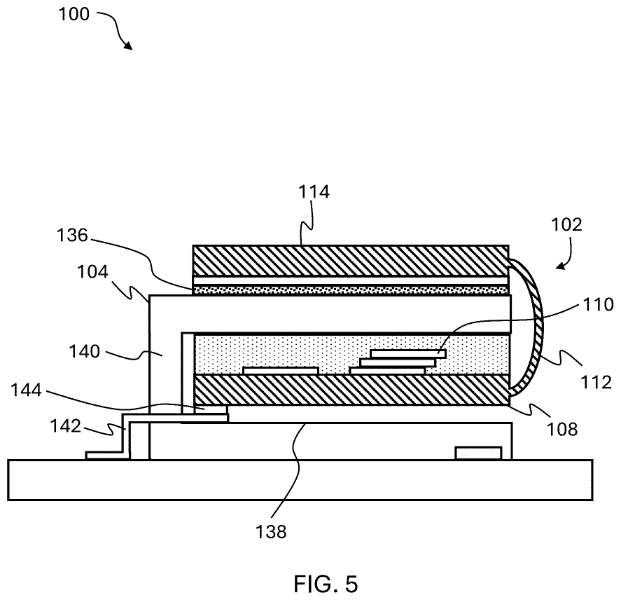

In some embodiments, the method may include mounting a heat spreader 114 to an exterior surface of the card socket 104. For example, and as illustrated by the arrow in FIG. 4, following connection of the first rigid substrate 108 to the slot interface 138 (e.g., as shown in FIG. 4) the heat spreader 114 is connected to the exterior surface of the housing 140 of card socket 104 (e.g., as shown in FIG. 5). In some embodiments, the TIM 136 adheres the heat spreader 114 to the housing 140 as discussed above. In some embodiments, the TIM 136 may be deposited on one or more of the housing 140 and heat spreader 114 prior to mounting the heat spreader 114 to the card socket 104.

In some embodiments, by providing the flexible substrate 112 coupling the first rigid substrate 108 to the heat spreader 114 the heat spreader 114 may be easily mounted to a surface for heat dissipation following connection of the first rigid substrate 108 to the card socket 104. For example, the heat spreader 114 is movable relative to the first rigid substrate 108 while remaining in electrical connection therewith via flexible substrate 112. Accordingly, the flexible substrate 112 may act as a physical tether attaching the heat spreader 114 to the first rigid substrate 108 and defining a range of movement for the heat spreader 114 relative to the first rigid substrate 108.

It will be appreciated by those skilled in the art that changes could be made to the exemplary embodiments shown and described above without departing from the broad inventive concepts thereof. It is understood, therefore, that this invention is not limited to the exemplary embodiments shown and described, but it is intended to cover modifications within the spirit and scope of the present invention as defined by the claims. For example, specific features of the exemplary embodiments may or may not be part of the claimed invention and various features of the disclosed embodiments may be combined. The words “right”, “left”, “lower” and “upper” designate directions in the drawings to which reference is made. Unless specifically set forth herein, the terms “a”, “an” and “the” are not limited to one element but instead should be read as meaning “at least one”. As used herein, the term “about” may refer to +/−10% of the value referenced. For example, “about 9” is understood to encompass 8.1 and 9.9.

It is to be understood that at least some of the figures and descriptions of the invention have been simplified to focus on elements that are relevant for a clear understanding of the invention, while eliminating, for purposes of clarity, other elements that those of ordinary skill in the art will appreciate may also comprise a portion of the invention. However, because such elements are well known in the art, and because they do not necessarily facilitate a better understanding of the invention, a description of such elements is not provided herein.

Further, to the extent that the methods of the present invention do not rely on the particular order of steps set forth herein, the particular order of the steps should not be construed as limitation on the claims. Any claims directed to the methods of the present invention should not be limited to the performance of their steps in the order written, and one skilled in the art can readily appreciate that the steps may be varied and still remain within the spirit and scope of the present invention.

What is claimed is:

1. A semiconductor device package comprising:
a first rigid substrate including an interconnect layer;
a semiconductor die electrically connected to and mounted directly on the first rigid substrate;
a flexible substrate electrically connected to and extending outwardly from the first rigid substrate, the flexible substrate including a thermally conductive layer that is electrically connected to the interconnect layer of the first rigid substrate; and
a heat spreader physically connected to the flexible substrate opposite the first rigid substrate, the heat spreader being electrically connected to the thermally conductive layer of the flexible substrate.

2. The semiconductor device package of claim 1, wherein the interconnect layer and thermally conductive layer form a continuous electrically conductive layer.

3. The semiconductor device package of claim 1, wherein the interconnect layer is an electrical ground plane of the first rigid substrate.

4. The semiconductor device package of claim 1, wherein the first rigid substrate is configured to be positioned within and electrically connected to a memory card socket and the heat spreader is configured to be mounted to an exterior surface of the memory card socket via a thermal interface material.

5. The semiconductor device package of claim 1, wherein the semiconductor die is mounted to a top surface of the first rigid substrate and the flexible substrate is physically connected to the first rigid substrate at a side surface thereof that extends between the top surface and an opposed bottom surface.

6. The semiconductor device package of claim 1, wherein the heat spreader includes a second rigid substrate that is physically connected to the flexible substrate and electrically connects the thermally conductive layer of the flexible substrate to a thermal conduction plate that is exposed at a bottom surface of the second rigid substrate.

7. The semiconductor device package of claim 6, wherein the thermal conduction plate is a layer of copper or a copper alloy that is electrically connected to the second rigid substrate and directly mounted to the bottom surface thereof.

8. The semiconductor device package of claim 6, wherein the thermally conductive layer is continuous and comprises a layer of copper or a copper alloy that extends through the first rigid substrate, the flexible substrate, and the second rigid substrate.

9. A semiconductor device system, comprising:
a semiconductor device package comprising:
a first rigid substrate including an interconnect layer;
a semiconductor die electrically connected to and mounted directly on the first rigid substrate;
a flexible substrate electrically connected to and extending outwardly from the first rigid substrate, the flexible substrate including a thermally conductive layer that is electrically connected to the interconnect layer of the first rigid substrate; and
a heat spreader physically connected to the flexible substrate opposite the first rigid substrate, the heat spreader being electrically connected to the thermally conductive layer of the flexible substrate; and
a card socket comprising:
a slot interface within which the first rigid substrate is positioned, the slot interface including an electrical contact that is electrically connected to a contact pad of the first rigid substrate; and
a housing surrounding the slot interface, the housing including an exterior surface upon which the heat spreader is mounted.

10. The semiconductor device system of claim 9, wherein the flexible substrate extends outside of the slot interface from the first rigid substrate to the heat spreader.

11. The semiconductor device system of claim 9 further comprising:
a thermal interface material adhering the heat spreader to the exterior surface of the housing.

12. The semiconductor device system of claim 9 further comprising:
a main circuit board including an electrical ground plane,
wherein the card socket is mounted to the main circuit board and the housing thereof is electrically connected to the electrical ground plane, and
wherein the interconnect layer is an electrical ground plane of the first rigid substrate.

13. The semiconductor device system of claim 9, wherein the heat spreader includes a second rigid substrate that is physically connected to the flexible substrate and electrically connects the thermally conductive layer of the flexible substrate to a thermal conduction plate that is exposed at a bottom surface of the second rigid substrate.

14. The semiconductor device system of claim 13, wherein the thermal conduction plate is adhered to the exterior surface of the housing via a thermal interface material.

16. The semiconductor device system of claim 13, wherein the thermally conductive layer is continuous and comprises a layer of copper or a copper alloy that extends through the first rigid substrate, the flexible substrate, and the second rigid substrate.

17. A method of connecting a semiconductor device package to a corresponding card socket, the method comprising:
positioning a first rigid substrate of the semiconductor device package within a slot interface of the card socket such that a semiconductor die mounted to the first rigid substrate is electrically connected to the slot interface; and
mounting a heat spreader to an exterior surface of the card socket, the heat spreader being electrically connected to an interconnect layer of the first rigid substrate via a flexible substrate that electrically connect to and extends outwardly from the first rigid substrate, the flexible substrate including a thermally conductive layer that is electrically connected to the interconnect layer of the first rigid substrate and to the heat spreader.

18. The method of claim 17, wherein mounting the heat spreader to the exterior surface of the card socket includes adhering an exposed thermally conductive plate of the heat spreader to the exterior surface via a thermal interface material.

19. The method of claim 17, wherein mounting the heat spreader to the exterior surface of the card socket causes the interconnect layer of the first rigid substrate to be electrically connected to an electrical ground plane of a main circuit board upon which the card socket is mounted.

20. The method of claim 17, wherein the thermally conductive layer is continuous and comprises a layer of copper or a copper alloy that extends through the first rigid substrate, the flexible substrate, and the heat spreader.
